(19) United States
(12) Patent Application Publication
(10) Pub. No.: US 2014/0313402 A1
(43) Pub. Date: Oct. 23, 2014

(54) WIRING SUBSTRATE AND CAMERA MODULE

(71) Applicant: SAMSUNG ELECTRO-MECHANICS CO., LTD., Suwon (KR)

(72) Inventors: Dae Wook Kim, Suwon (KR); Sang Jin Lee, Suwon (KR)

(21) Appl. No.: 13/938,764

(22) Filed: Jul. 10, 2013

(30) Foreign Application Priority Data
Apr. 23, 2013 (KR) 10-2013-0044702

(51) Int. Cl. H05K 1/11; H04N 5/225

(52) U.S. Cl. CPC H05K 1/11; H04N 5/2251
USPC 348/373; 174/261

(57) ABSTRACT

There is provide a wiring substrate, including: a first connection part formed on one side thereof; a second connection part formed on the other side thereof; and an intermediate part formed between the first and second connection parts and having one or more pleats formed therein.

### CROSS-REFERENCE TO RELATED APPLICATIONS

This application claims the priority of Korean Patent Application No. 10-2013-0044702 filed on Apr. 23, 2013, in the Korean Intellectual Property Office, the disclosure of which is incorporated herein by reference.

### BACKGROUND OF THE INVENTION

1. Field of the Invention

The present invention relates to a camera module, and more particularly, to a wiring substrate in which separated components maybe easily connected to one another and a camera module which is easily mounted on a portable terminal device.

2. Description of the Related Art

Electronic devices such as mobile phones and portable terminals are evolving to become more sophisticated and have various capabilities. As an example, camera modules for capturing images are commonly mounted on portable electronic devices.

As the capability and performance of such camera modules are consistently improved, it becomes difficult to reduce the size of the camera module. However, portable electronic devices are increasingly being reduced in size, and space for mounting camera modules in portable electronic devices is gradually being reduced.

Accordingly, camera modules which can be easily mounted in a limited space are in demand.

In this regard, as related art, there is provided Patent Document 1. Patent Document 1 discloses that a slit 88 is formed in a flexible wiring substrate 30 so as to allow the distance between a CCD element 36 and a connector 29 to be adjustable.

However, in Patent Document 1, the fact that a substantially long relay part 94 is required to allow the distance between the CCD element 36 and the connector 29 to be adjusted is a shortcoming. In addition, in Patent Document 1, it is disadvantageous in that the relay part 94 is extended in the longitudinal direction of the wiring substrate 30 so that a substantial amount of space is required for mounting an imaging module 26 on a portable terminal.

### RELATED ART DOCUMENT

(Patent Document 1) Japanese Patent Laid-open Publication No. 2009-128521 A

### SUMMARY OF THE INVENTION

An aspect of the present invention provides a wiring substrate suitable for usage in a limited space, and a camera module suitable for being mounted in a limited space.

According to an aspect of the present invention, there is provided a wiring substrate, including: a first connection part formed on one side thereof; a second connection part formed on the other side thereof; and an intermediate part formed between the first and second connection parts and having one or more pleats formed therein.

The pleats may be arc-shaped and have a radius of between 0.2 and 0.8 mm in a longitudinal cross-section.

The pleats may be arc-shaped and have a radius of 0.4 mm in a longitudinal cross-section.

A thickness of the intermediate part may be between 120 and 200 μm.

A thickness of the intermediate part may be 140 μm.

The pleats may include: first pleats protruding upwardly and having a radius of a first dimension in a longitudinal cross-section of the wiring substrate; and second pleats protruding downwardly and having a radius of a second dimension in the longitudinal cross-section of the wiring substrate, wherein the first dimension and the second dimension are the same as or different from each other.

The intermediate part may have one or more grooves formed therein for facilitating bending thereof to the left and right.

The groove may include: a first groove formed along a first side of the intermediate part; and a second groove formed along a second side of the intermediate part, wherein the first groove and the second groove are arranged in a zigzag manner.

The first connection part may have an anisotropic adhesive film (ADF) formed thereon, and the second connection part may have a connection terminal mounted thereon, the connection terminal including a plurality of connection pins.

According to another aspect of the present invention, there is provided a camera module, including: a lens unit; a connection terminal; and a wiring substrate electrically connecting an image sensor of the lens unit to the connection terminal and having a plurality of pleats formed thereon.

The pleats may be arc-shaped and have a radius of 0.4 mm in a longitudinal cross-section.

The pleats may be arc-shaped and have a radius of 0.4 mm in a longitudinal cross-section.

The wiring substrate may include: a first connection part connected to the image sensor; a second connection part connected to the connection terminal; and an intermediate part connecting the first connection part to the second connection part.

A thickness of the intermediate part may be between 120 and 200 μm.

A thickness of the intermediate part may be 140 μm.

The pleats may include: first pleats protruding upwardly and having a radius of a first dimension in a longitudinal cross-section of the wiring substrate; and second pleats protruding downwardly and having a radius of a second dimension in the longitudinal cross-section of the wiring substrate, wherein the first dimension and the second dimension are the same as or different from each other.

The intermediate part may have one or more grooves formed therein for facilitating bending thereof to the left and right.

The groove may include: a first groove formed along a first side of the intermediate part; and a second groove formed along a second side of the intermediate part, wherein the first groove and the second groove are arranged in a zigzag manner.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a wiring substrate according to an embodiment of the present invention;

FIG. 2 is a side view of portion A shown in FIG. 1;

FIG. 3 is a side view of portion A shown in FIG. 1 having a different shape;

FIG. 4 is a side view of portion A shown in FIG. 1 having another different shape;

FIGS. 5A to 5C are side views of embodiments of the wiring substrate shown in FIG. 1;

FIGS. 6A to 6C are plan views of embodiments of the wiring substrate shown in FIG. 1;

FIG. 7 is a perspective view of a wiring substrate according to another embodiment of the present invention;

FIG. 8 is a perspective view showing another shape of the wiring substrate shown in FIG. 7;

FIG. 9 is a perspective view showing another shape of the wiring substrate shown in FIG. 7; and

FIG. 10 is a perspective view of a camera module according to an embodiment of the present invention.

### DETAILED DESCRIPTION OF THE INVENTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements maybe exaggerated for clarity, and the same reference numerals will be used throughout to designate the same or like elements.

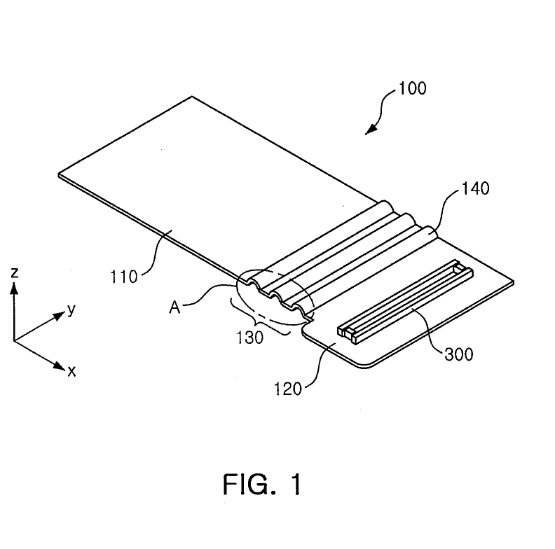

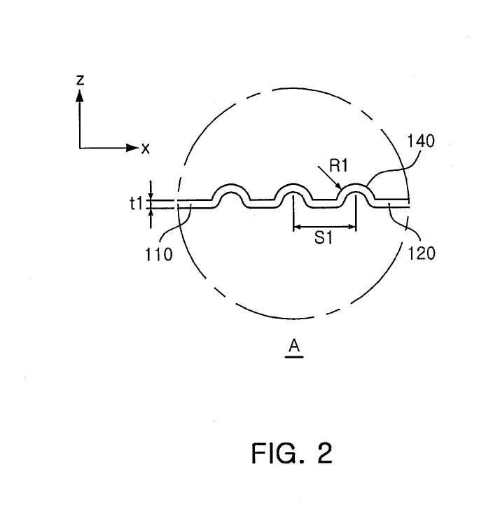

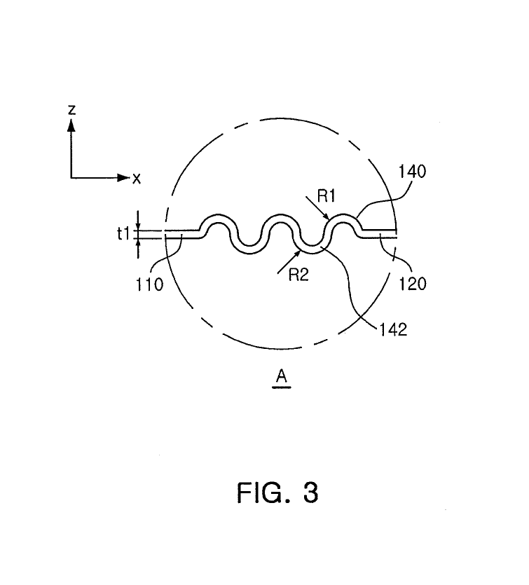

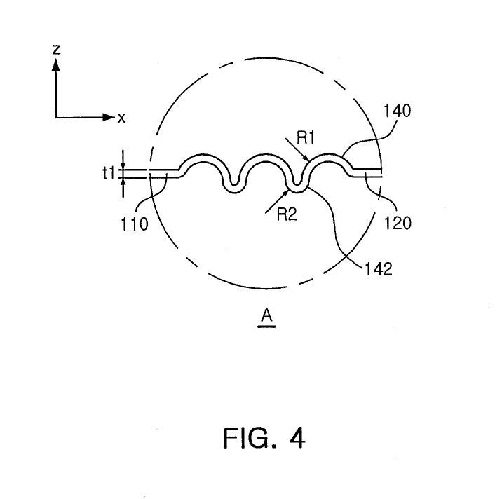

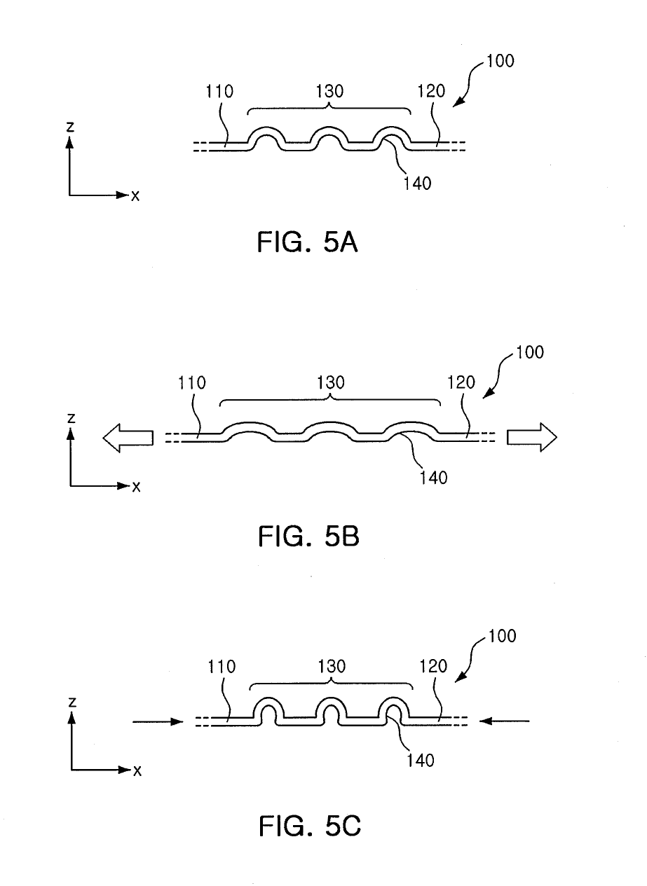

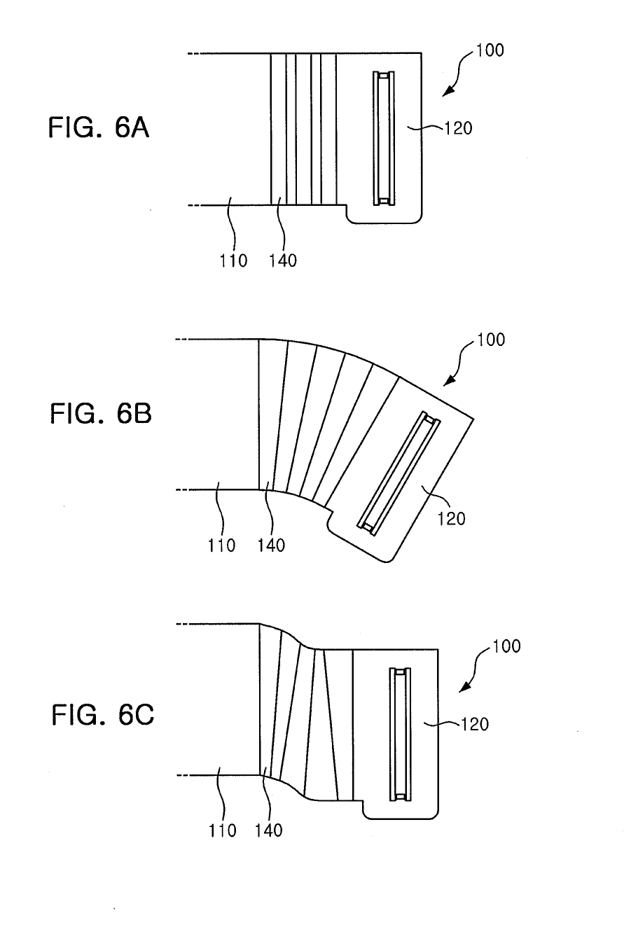

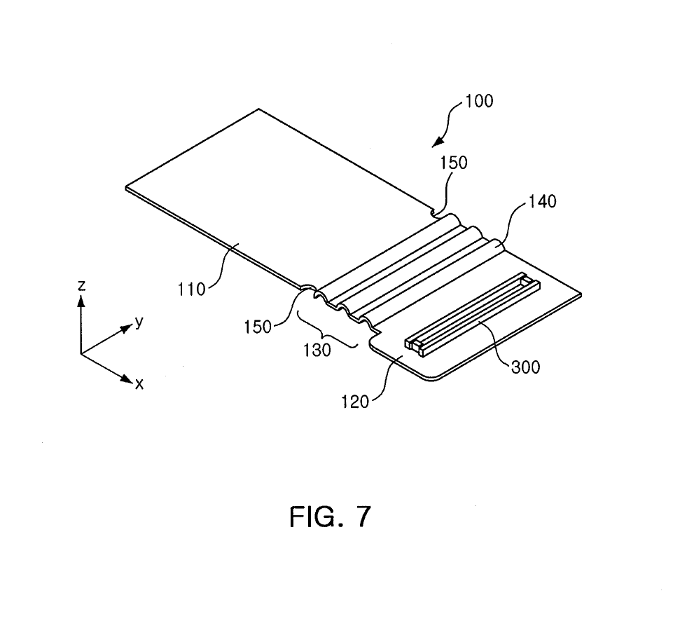

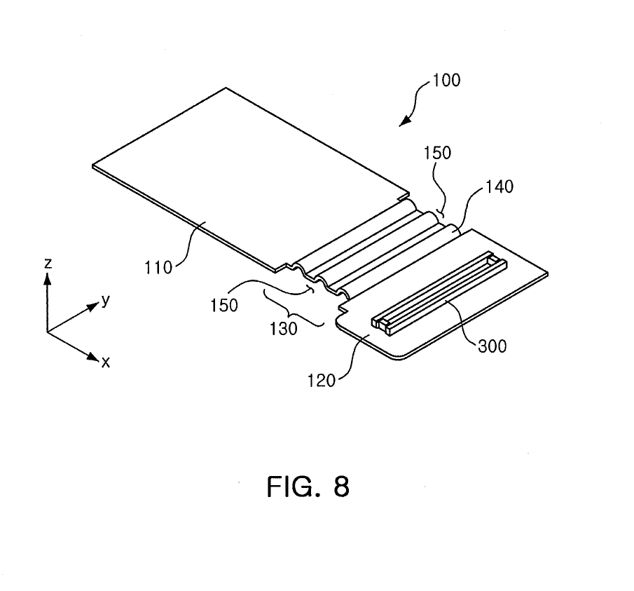

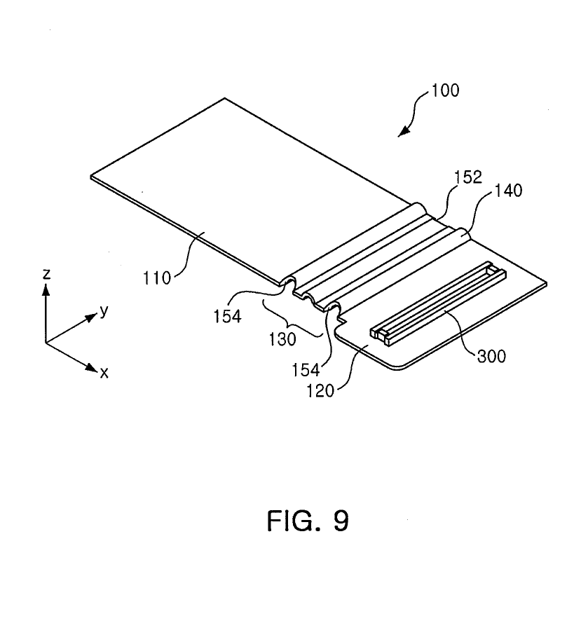

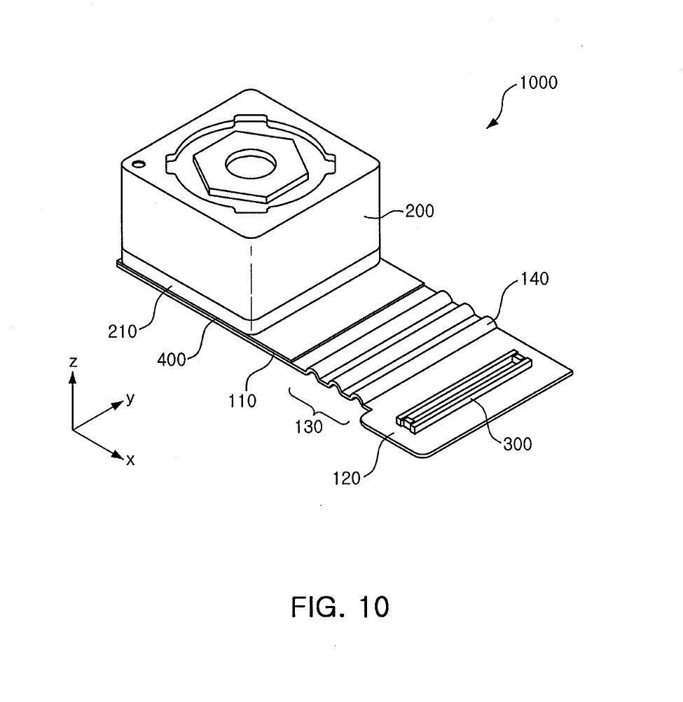

FIG. 1 is a perspective view of a wiring substrate according to an embodiment of the present invention; FIG. 2 is a side view of portion A shown in FIG. 1; FIG. 3 is a side view of portion A shown in FIG. 1 having a different shape; FIG. 4 is a side view of portion A shown in FIG. 1 having another different shape; FIGS. 5A to 5C are side views of embodiments of the wiring substrate shown in FIG. 1; FIGS. 6A to 6C are plan views of embodiments of the wiring substrate shown in FIG. 1; FIG. 7 is a perspective view of a wiring substrate according to another embodiment of the present invention; FIG. 8 is a perspective view showing another shape of the wiring substrate shown in FIG. 7; FIG. 9 is a perspective view showing another shape of the wiring substrate shown in FIG. 7; and FIG. 10 is a perspective view of a camera module according to an embodiment of the present invention.

A wiring substrate according to an embodiment of the present invention will be described with reference to FIGS. 1 to 6.

The wiring substrate 100 according to the embodiment of the present invention may be a substrate on which circuit patterns are printed. Specifically, the wiring substrate 100 may be formed by printing conductive metals on a film made of a resin material. The resin material, which mainly composes the wiring substrate 100, may be polyimide. The resin material, however, may be replaced by or selected from resin materials other than polyimide, as needed. Moreover, the conductive metal may be any metal having a high degree of conductivity such as Cu and Ag, or may be an alloy metal including Cu or Ag.

The wiring substrate 100 may be a flexible substrate. That is, the wiring substrate 100 may be made of resin material and may be freely bent. If necessary, only a part of the wiring substrate 100 may be made of resin material so that only the part may be bent.

The wiring substrate 100 may be used for connecting two or more electronic components adjacent to or distant from each other. For example, the wiring substrate 100 may connect an image sensor of a lens unit to a main circuit board of a portable electronic device. However, the wiring substrate 100 is not limited to connecting the image sensor and the main circuit board but may connect other electronic components to each other, as needed.

The wiring substrate 100 may include a first connection part 110, a second connection part 120, and an intermediate part 130. In addition, the wiring substrate 100 may further include a connection terminal 300 to facilitate the electrical connection between the electronic component and the main circuit board. It is to be noted that although FIG. 1 shows the connection terminal 300 being formed only on the second connection part 120 of the wiring substrate 100, the connection terminal 300 may be formed on both the first connection part 110 and the second connection part 120, as needed.

The first connection part 110 may be formed on one side of the wiring substrate 100. Specifically, the first connection part 110 may be a part of the wiring substrate 100 on which printed circuit patterns (not shown) are exposed. The first connection part 110 may be connected to an electronic component. To this end, the first connection part 110 may have a connection terminal. Alternatively, the first connection part 110 may be able to have an electronic component mounted thereon. For example, the first connection part 110 may expose terminals of printed circuit patterns thereon in a certain pattern, and an electronic component may be connected to the printed circuit patterns by soldering, wire bonding, bonding with anisotropic adhesive film and the like.

The first connection part 110 may be a part of the wiring substrate 100 having a predetermined degree of rigidity. Specifically, the first connection part 110 may be a rigid substrate made of ceramic, for example. However, the material or property of the first connection part 110 is not limited to the rigid substrate but may also be a flexible substrate of film material, as needed.

The second connection part 120 may be formed on the other side of the wiring substrate 100. Specifically, the second connection part 120 may be another part of the wiring substrate 100 on which printed circuit patterns (not shown) are exposed. The second connection part 120 may be connected to another electronic component. To this end, the second connection part 120 may have a connection terminal. Alternatively, the second connection part 120 may be able to have an electronic component mounted thereon. For example, the second connection part 120 may expose terminals of printed circuit patterns thereon in a certain pattern, and an electronic component may be connected to the printed circuit patterns by soldering, wire bonding, bonding with anisotropic adhesive film and the like. It is to be noted that in this embodiment a connection terminal 300 connected to the second connection part 120 may be formed as shown in FIG. 1.

The second connection part 120 may be a part of the wiring substrate 100 having a predetermined degree of rigidity. Specifically, the second connection part 120 may be a rigid substrate made of ceramic, for example. However, the material or property of the second connection part 120 is not limited to the rigid substrate but may also be a flexible substrate.

The intermediate part 130 may be formed between the first connection part 110 and the second connection part 120. Specifically, in this specification, the intermediate part 130 may refer to all of the region between the first connection part 110 and the second connection part 120. The intermediate part 130 may be a part of the wiring substrate 100 which is flexible. Specifically, the intermediate part 130 may be formed of a material different from the materials of the first and second connection parts 110 and 120. That is, the intermediate part 130 may be a flexible substrate connecting the first connection part 110 and the second connection part 120 which are rigid substrates. However, the material and property of the intermediate part 130 are not limited to being different from those of the first and second connection parts 110 and 120, but may be the same as those of the first and second connection parts 110 and 120, as needed.

The intermediate part 130 may have a predetermined thickness (t), as shown in FIG. 2. Specifically, the thickness (t) of the intermediate part 130 may be 120 to 200 μm, and preferably 140 μm. Here, 200 μm is the maximum thickness allowing the substrate to be bent, and 120 μm is the minimum thickness allowing the substrate to include printed circuit patterns thereon.

The intermediate part 130 may have pleats (140) formed therein. Specifically, the intermediate part 130 may have a plurality of pleats 140 arranged in the longitudinal direction of the wiring substrate 100 (in the x direction in FIG. 1). It is to be noted that although FIG. 1 shows three pleats 140 formed on the intermediate part 130, the number of pleats 140 formed on the intermediate part 130 is not limited to three but may be increased or decreased as required.

The pleats 140 may be composed of one or more curve(s). In detail, the side surface of the part of the intermediate part 130 where the pleats 140 are formed may generally be an arc-like curve as shown in FIG. 2. Here, the radius R1 of the arc may be 0.2 to 0.8 mm, and preferably 0.4 mm. It is to be noted that 0.2 mm is the minimum dimension allowing the wiring substrate 100 to contract and expand (in the x direction in FIG. 1) through the pleats 140, and 0.8 mm is the optimized dimension allowing a plurality of pleats 140 to be formed on the intermediate part 130 having a predetermined length. That is, if the radius R1 of the arc is greater than 0.8 mm, the number of pleats 140 formed on the intermediate part 130 may be less than when the radius R1 is between the optimized ranges (0.2 to 0.8 mm). The distance S1 between the pleats 140 may be greater than the radius R1 of the pleats 140. However, the distance S1 may not be greater than the radius R1 but may be any value, chosen as needed.

Further, the shape of the pleats 140 and 142 of the intermediate part 130 may be changed to those shown in FIGS. 3 and 4.

That is, first pleats 140 and second pleats 142 according to a embodiment may be formed so that plural arcs having the same radii R1 and R2 alternate up and down, as shown in FIG. 3. The pleats 140 and 142 shown in FIG. 3 have the arcs of the same radii, such that they may be easily formed with a jig.

Alternatively, first pleats 140 and second pleats 142 according to another embodiment may be formed so that plural arcs having different radii R1 and R2 alternate up and down, as shown in FIG. 4. The pleats 140 and 142 shown in FIG. 4 may be differently expanded and contracted by the force applied from the outside of the wiring substrate 100, such that arrangements of the wiring substrate 100 may be precisely adjusted.

The wiring substrate 100 thus configured may easily connect electronic components, located at a longer or shorter distance than estimated, to one another at the time of designing by deforming the intermediate part 130, as shown in FIG. 5. Specifically, the wiring substrate 100 may increase or decrease the distance between the first connection part 110 and the second connection part 120 by expanding or contracting the pleats 140. Accordingly, the wiring substrate 100 according to the embodiment may easily connect electronic components to one another even if the distance between the electronic components deviates from the designed specification.

Moreover, the wiring substrate 100 according to the embodiment may easily connect unaligned electronic components to one another by deforming the intermediate part 130 as shown in FIG. 6. Specifically, the wiring substrate 100 may bend in the y direction by asymmetrically deforming the pleats 140 as shown in FIG. 6. Accordingly, the wiring substrate 100 according to the embodiment may easily connect electronic components to one another even if the electronic components are not in a line, not as designed.

Now, a wiring substrate according to another embodiment of the present invention will be described with reference to FIGS. 7 through 9. In the following description of the embodiments, the same reference numerals will be used to denote the same elements as those of the previous embodiment, the detailed descriptions of which will be omitted.

The wiring substrate 100 according to the embodiment of the present invention may include a groove 150. Specifically, the wiring substrate 100 may have one or more groove(s) 150 formed in the intermediate part 130.

The groove 150 may be formed anywhere in the intermediate part 130. Specifically, the groove 150 may be formed on both sides of the intermediate part 130, and may be formed at a part with or without the pleats 140 formed.

Specifically, the groove 150 may be formed in a part without the pleats 140 as shown in FIG. 7, or may be formed in a part with the pleats 140 as shown in FIGS. 8 and 9. In addition, the groove 150 may be formed along and over the entire part with the pleats 140 as shown in FIG. 8, or may be formed in zigzag (i.e., asymmetrically) on both sides of the intermediate part 130 as shown in FIG. 9. The groove 150 formed in the intermediate part 130 may facilitate bending or deforming of the wiring substrate 100 in the y direction (in FIG. 7).

Next, a camera module according to another embodiment of the present invention will be described with reference to FIG. 10.

The camera module 1000 according to the embodiment of the present invention may include a wiring substrate 100, a lens unit 200, and a connection terminal 300. The camera module 1000 may further include an anisotropic adhesive film (ADF) 400 in order to easily bond the lens unit 200 and the wiring substrate 100. The wiring substrate 100 may have the same or a similar shape and may have the same or similar characteristics to the wiring substrate shown in FIGS. 1 through 9. Specifically, the intermediate part 130 of the wiring substrate 100 may have a plurality of pleats 140 allowing the wiring substrate 100 to be deformed in the x and y directions.

The lens unit 200 may include one or more lens and an image sensor 210. Specifically, the lens unit 200 may include a plurality of lenses for clearly projecting an image of a subject onto the image sensor 210. The lens unit 200 may be connected to the first connection part 110 of the wiring substrate 100. Specifically, the image sensor 210 of the lens unit 200 may be connected to the wiring substrate 100 by the anisotropic adhesive film 400.

The camera module 1000 according to the embodiment has the following advantages:

Firstly, the length of the wiring substrate may be reduced.

The camera module 1000 according to the embodiment may adjust the distance between the first connection part 110 and the second connection part 120 by the pleats 140 of the intermediate part 130, and thus the wiring substrate 100 need not be unnecessarily long. Therefore, the wiring substrate 100 of the camera module 1000 according to the embodiment may be shorter than that of a typical camera module, thereby reducing manufacturing costs of the camera module 1000.

Secondly, the rate of failure due to breakage of the wiring substrate may be reduced.

In the camera module 1000 according to the embodiment, the wiring substrate 100 is not bent in the vertical direction; contact failures on the wiring substrate 100 may be minimized. Specifically, in the camera module 1000, the wiring substrate 100 has curve-shaped pleats 140, the wiring substrate 100 may be easily folded or bent. Therefore, the wiring substrate 100 of the camera module 1000 according to the embodiment may reduce the rate of failure of the camera module 1000 due to breakage of the wiring substrate 100.

Thirdly, limitations on installation space may be reduced.

That is, in the camera module 1000 according to the embodiment, the wiring substrate 100 may be freely deformed by virtue of the pleats 140, such that the camera module 1000 and a main circuit board of a portable electronic device may be easily connected even when a space for installing the camera module 1000 is so small.

As set forth above, according to embodiments of the present invention, electronic components mounted in a limited space can be easily connected.

Further, according to embodiments of the present invention, the camera module can be easily mounted on a small electronic device without limitations on the installation space.

While the present invention has been shown and described in connection with the embodiments, it will be apparent to those skilled in the art that modifications and variations can be made without departing from the spirit and scope of the invention as defined by the appended claims.

What is claimed is:

1. A wiring substrate, comprising:
a first connection part formed on one side thereof;
a second connection part formed on the other side thereof; and
an intermediate part formed between the first and second connection parts and having one or more pleats formed therein.

2. The substrate of claim 1, wherein the pleats are arc-shaped and have a radius of between 0.2 and 0.8 mm in a longitudinal cross-section.

3. The substrate of claim 1, wherein the pleats are arc-shaped and have a radius of 0.4 mm in a longitudinal cross-section.

4. The substrate of claim 1, wherein a thickness of the intermediate part is between 120 and 200 μm.

5. The substrate of claim 1, wherein a thickness of the intermediate part is 140 μm.

6. The substrate of claim 1, wherein the pleats includes:
arc-shaped first pleats protruding upwardly and having a radius of a first dimension in a longitudinal cross-section of the wiring substrate; and
arc-shaped second pleats protruding downwardly and having a radius of a second dimension in the longitudinal cross-section of the wiring substrate,
wherein the first dimension and the second dimension are the same as or different from each other.

7. The substrate of claim 1, wherein the intermediate part has one or more grooves formed therein for facilitating bending thereof to the left and right.

8. The substrate of claim 7, wherein the groove includes:
a first groove formed along a first side of the intermediate part; and
a second groove formed along a second side of the intermediate part,
wherein the first groove and the second groove are arranged in a zigzag manner.

9. The substrate of claim 1, wherein the first connection part has an anisotropic adhesive film (ADF) formed thereon, and wherein the second connection part has a connection terminal mounted thereon, the connection terminal including a plurality of connection pins.

10. A camera module, comprising:
a lens unit;
a connection terminal; and
a wiring substrate electrically connecting an image sensor of the lens unit to the connection terminal, and having a plurality of pleats formed thereon.

11. The camera module of claim 10, wherein the pleats are arc-shaped and have a radius of between 0.2 and 0.8 mm in a longitudinal cross-section.

12. The camera module of claim 10, wherein the pleats are arc-shaped and have a radius of 0.4 mm in a longitudinal cross-section.

13. The camera module of claim 10, wherein the pleats includes:
first pleats protruding upwardly and having a radius of a first dimension in a longitudinal cross-section of the wiring substrate; and
second pleats protruding downwardly and having a radius of a second dimension in the longitudinal cross-section of the wiring substrate, wherein the first dimension and the second dimension are the same as or different from each other.

14. The camera module of claim 10, wherein the wiring substrate includes:
a first connection part connected to the image sensor;
a second connection part connected to the connection terminal; and
an intermediate part connecting the first connection part to the second connection part.

15. The camera module of claim 14, wherein a thickness of the intermediate part is between 120 and 200 μm.

16. The camera module of claim 14, wherein a thickness of the intermediate part is 140 μm.

17. The camera module of claim 14, wherein the intermediate part has one or more grooves formed therein for facilitating bending thereof to the left and right.

18. The camera module of claim 17, wherein the groove includes:
a first groove formed along a first side of the intermediate part; and
a second groove formed along a second side of the intermediate part,
wherein the first groove and the second groove are arranged in a zigzag manner.
